(19) United States
(12) Patent Application Publication
(10) Pub. No.: US 2006/0244345 A1
(43) Pub. Date: Nov. 2, 2006

(54) Pluggable terminal block assembly for audible signal alarm power connection

(75) Inventors: George A. Burnett, Clayton, IN (US); Joshua K. Brown, Danville, IN (US)

Correspondence Address: Robert F. Meyer, 4411 South High School Rd, Indianapolis, IN, 46241-6404, US

(73) Assignee: Mallory Sonalert Products, Inc.

(21) Appl. No.: 11/119,032

(22) Filed: May 2, 2005

(51) Int. Cl. H01L 41/053

(52) U.S. Cl. 310/348

(57) ABSTRACT

Piezoelectric alarm devices are held in a plastic housing with flat bladed electrical terminals carried on the outside of the housing. These terminals are being replaced by a pluggable terminal block assembly which can be readably integrated into the housing. The assembly includes a header which is encapsulated in the housing.

### BACKGROUND OF THE INVENTION

The present invention relates to piezoelectric alarm devises and more particularly to the connection of electrical leads to the device.

Piezoelectric alarm devices have been in use for many years. Generally speaking such devices include a piezoelectric transducer and a circuit board electrically connected to the transducer both of which are carried in a housing having outlets through which sound waves are emitted. An example of such a devise can be found in U.S. Pat. No. 3,815,219 which is incorporated herein by reference.

Prior to the present invention, electrical power was supplied to the circuit board through flat bladed terminals that are connected to the user power source by wires that are either soldered onto the flat bladed terminals or by attaching the spade connector onto a wire and then securing it onto the flat bladed terminal by a screw. This arrangement results in very little flexibility in changing connections and result in longer assembly times.

### OBJECTS OR FEATURES OF THE INVENTION

It is therefore an object of the invention to provide a more flexible power connection to a piezoelectric alarm device and one that is easier and quicker to assemble.

Another object of the invention is to provide a plug-in type of electrical connection to the device.

Yet another object of the invention is to provide a plug-in type electrical connection wherein a terminal block engages a header that is encapsulated in a housing carrying a circuit board and a piezoelectric transducer.

### SUMMARY OF THE INVENTION

Accordingly there is provided a piezoelectric alarm device which, in general, comprises a housing; a circuit board carried in the housing and electrically connected to a piezoelectric transducer carried in the housing; a header encapsulated in the housing and including first electrical connections connected to the circuit board; a terminal block engaging the header, second electrical connections carried in the terminal block and engaging the first electrical connections, and terminals adapted to receive electrical leads to be electrically connected to the second electrical connections; and outlets in the housing through which sound is emitted.

### DESCRIPTION OF THE DRAWINGS

FIG. 1 is a partial cross-section of piezoelectric alarm device employing the invention.

FIG. 2 is a partial cross-section of a terminal block used in the invention.

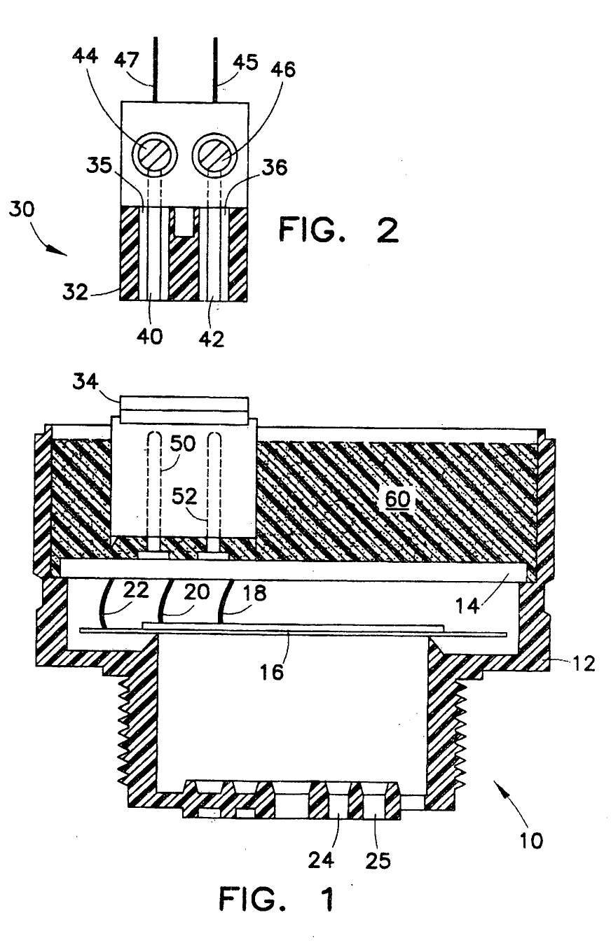

### DETAILED DESCRIPTION OF THE INVENTION

Referring to the drawings there is shown a piezoelectric alarm device 10. In general, the device includes a housing 12 in which is carried a circuit board 14 and a piezoelectric transducer 16 also carried in the housing. Electrical leads 18, 20, and 22 electrically connect the circuit board to the piezoelectric transducer. Apertures 24 and 25 provide an outlet for sound waves emitted from the transducer.

In accordance with the invention there is provided a plug-in type terminal connection 30 for supplying electrical power to the circuit board 14. Plug-in terminal connection 30 includes a terminal block 32 and header 34. Terminal block 32 includes passage ways 35 and 36 and sleeves 40 and 42 extending the length of the passage ways and up to terminals 44 and 46 to provide an electrical connection to the terminals. As shown in the present embodiment, terminals 44 and 46 include screws to which electrical leads 45 and 47 can be attached in a well known manner.

Header 34 includes posts 50 and 52 which are in electrical contact with circuit board 14. When terminal block 32 engages the header, sleeves 40 and 42 engage posts 50 and 52 to provide an electrical connection between the sleeves and the posts.

Thus when electrical power is applied to leads 45 and 47, power is applied to circuit board 14 from the leads through sleeves 40 and 42 and posts 50 and 52.

This plug-in type terminal block arrangement provides for a quick assembly and more flexibility than the normally used flat bladed terminals. It also allows for quick and easy removal during times of service.

As shown, header 34 is encapsulated within the housing 12 by an encapsulating material 60. This provides a device that is rugged and intrinsically safe. This is especially desirable when a plug-in type terminal assembly is used by permitting frequent changes without mis-orienting the header. A suitable encapsulating material would be an epoxy. An example of a suitable epoxy is one provided by Specialty Polymers and Services of Valencia, Calif. which is a two part system consisting of one part resin and one part hardener.

1-2. (canceled)

3. A piezoelectric alarm device comprising:
a) a housing,
b) a circuit board carried in said housing and electrically connected to a piezoelectric transducer carried in said housing;
c) an encapsulating material carried in said housing;
d) a header carried in said encapsulating material to be encapsulated in said housing, said header including first electrical connections connected to said circuit board,
e) a terminal block engaging said header, second electrical connections carried in said terminal block engaging said first electrical connections and terminals receiving electrical leads to be electrically connected to said second electrical connections; and
f) outlets in said housing through which sound is emitted.

4. A piezoelectric alarm device according to claim 3 wherein said encapsulating material is an epoxy.
